(19) United States
(12) Patent Application Publication
(10) Pub. No.: US 2007/0146713 A1
(43) Pub. Date: Jun. 28, 2007

(54) Method for identifying effect pigments in a paint film for field color matching

(76) Inventors: David H. Alman, Royal Oak, MI (US); Thomas C. Phelan, Havre De Grace, MD (US); Jebby K. Tommy, Macomb, MI (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/546,670

(22) PCT Filed: Apr. 28, 2004
(86) PCT No.: PCT/US04/13695

§ 371 Date: Aug. 22, 2005

Related U.S. Application Data
(63) Continuation-in-part of application No. 10/426,223, filed on Apr. 30, 2003, now abandoned.

(51) Int. Cl. C23C 16/52

(52) U.S. Cl. 356/421; 427/8

(57) ABSTRACT

The present method invention provides a portable method useful for identifying the effect pigments used in developing a color matched formula for a vehicle repair paint. The method comprises observation of effect pigment properties of the coating of a vehicle to be matched, in a field location with a portable magnification apparatus, and comparison of the effect pigment properties with reference sample(s) properties of available effect pigments, thus enabling precise selection of effect pigment(s). The method may also utilize features derived from images of physical reference samples of available effect pigments, for comparison purposes. Further, the method may, in a field or centralized laboratory location, utilize a comparison of the effect pigment properties of images of the vehicle coating to be matched, or features derived from images thereof, with images of reference samples of available effect pigments, or features derived from images thereof, thus enabling precise selection the effect pigment or pigments to use in the development of said color matched formula.

### BACKGROUND OF THE INVENTION

1. Field of the Invention

This invention is directed to a method for characterizing the color properties of a paint or coatings film containing effect pigments, and in particular to a mobile or portable method for classifying effect pigment properties in the field to efficiently develop custom color matched formulations and coatings.

2. Description of the Related Art

The refinish (i.e., collision repair) coatings industry depends highly on the ability to prepare a formulation or coating composition which has excellent color match with original equipment manufacturers' (OEM) color coating. It is especially difficult to provide excellent color matches to a vehicle's original finish when the OEM color coating contains effect pigments such as pearl and aluminum flakes. The difficulty lies in accurately and efficiently classifying useful properties of the OEM coating's effect pigments, which give the coating a unique visual effect depending on the original morphology and type of pigment employed.

Traditional approaches to obtain effect pigment properties include visual comparison of the OEM coating to reference samples with the various effect pigments, or sending an OEM coated part to a central laboratory for microscope analysis. An example of the latter is provided in Raimund Schmid, Identification of effect pigments for color matching, BASF, as well as in Microscopic evaluation of effect colors—Approach to color matching, Ingrid, Denne, CPMA conference, Charlotte, N.C., Apr. 17-19, 2000.

Visual comparison to reference samples presents several difficulties. Visual flake appearance depends on just a few visual features so that there is relatively little information for classifying flakes. The sample appearance also depends on lightness, color and other pigments in the color so that it is difficult to compare (for example, a flake reference sample in a silver color to a medium red metallic/pearl test color). Most effect colors have a blend of two or more flakes. Determining the composite visual appearance created by two or more flakes from reference samples of single flakes is not effective. Further, sending an OEM coated part to a central laboratory for microscope analysis can be inefficient, costly, and is not considered mobile or portable.

Therefore, there is a need for a mobile or portable method for classifying effect pigment properties in the field which is useful to efficiently develop custom color matched formulations and coatings.

### SUMMARY OF THE INVENTION

The present invention provides a portable method useful for identifying the effect pigments used in developing a color matched formula for a vehicle repair paint. The method comprises:
(a) visually observing the effect pigment properties (e.g., size, morphology, and color features) of the original coating on a vehicle to be matched or repaired, in a field location with a portable magnification apparatus (e.g., a handheld portable microscope); and
(b) comparing the effect pigment properties observed in step (a), with physical reference sample(s) properties of available effect pigments, thus enabling precise effect pigment(s) selection.

Also, the method may utilize features derived from images of physical reference samples of available effect pigments, for comparison purposes.

The method may be based upon comparison, in a field or centralized laboratory location, of the effect pigment properties of images of the vehicle coating to be matched, with the properties of images derived from physical reference samples of available effect pigments. Further, the method of the present invention may compare effect pigment features derived from images of the coating to be matched, with features derived from images of reference samples.

### BRIEF DESCRIPTION OF THE DRAWINGS

FIG. 1 is a general flow chart describing the method for classifying effect pigments for field color matching, in accordance with the present invention.

FIG. 2 is a magnified image of E. I. Du Pont de Nemours & Co. repair clearcoat/colorcoat composite paint (code P0961K V10) containing aluminum effect pigment (code 895J) and copper mica pearl effect pigment (code 1006S). The actual size of the image area is approximately 220×165 micrometers.

FIG. 3 is a side elevational view of a handheld portable microscope, Model ME4130 from Micro Enterprises Inc, Norcross, Ga., that can be employed in the method of the present invention.

FIG. 4 is a schematic diagram illustrating co-axial illumination and observation directions produced by a beam splitter in a preferred portable microscope embodiment.

FIG. 5 is a general flow diagram showing an example of an effect pigment classification scheme which can be employed in the present invention.

### DETAILED DESCRIPTION OF THE PREFERRED EMBODIMENTS

The method of the present invention enables one to offer a custom color formula development capability for metallic/pearl colors at point of sale in the field, such as an automotive refinish paint distributor, an automotive body repair facility, and the like. More particularly, the method of the present invention enables one to accurately identify the effect pigments to use in developing a color matching formula for a vehicle repair paint, at a field location. The method eliminates the significant delay previously encountered in developing custom colors for an automobile repair, due to shipment of original painted vehicle parts (typically a fuel door) for analysis of the effect pigment containing colors to a central laboratory environment.

Effect pigment classification is a necessary first step for effect color matching. Combined with existing multi-angle spectral reflectance measurement, pigment mixture models and computer color matching software, a complete field custom color match capability is now possible.

It is commonplace that the paint and vehicle manufacturers change the effect pigmentation after distribution of official paint samples, or standards. In this case the refinish paint distributor may get additional samples by getting car part samples from repair facilities. This imposes shipping expense and delay in obtaining an accurate color match. The invention operates in the field to eliminate shipping expense and delay and to work on the actual color to be matched.

Special lighting or operators with special visual color experience are not necessarily required in the method of the invention. Microscope imaging is utilized to observe the effect pigments. This allows direct comparison of pigment micro features instead of comparison of appearances which depend upon other factors.

The present invention is an improvement over prior systems difficulties by utilizing microscopic analysis of effect pigments on a vehicle coated surface, in the field, and not in a laboratory setting. The present invention provides better flake feature discrimination than non-microscopic visual observation and eliminates the need to send car parts to the microscope facility. The actual analysis is performed through comparison of microscopic observations, or images, of the coated surface in question, with either reference samples, images of reference samples, or features derived from images of reference samples. Such comparison may be conducted in the field at the point of sale, or even in conjunction with a centralized location to which images are transmitted. Subsequent to such comparison, selection of appropriate effect pigment, or effect pigments, may be done.

The method of the present invention can be used for developing a custom color matched formula for virtually any coating type. The present invention is particularly useful for developing a color matched automotive finishing primer, primer surfacer, or topcoat which may be a either a monocoat, clearcoat/colorcoat composite, and the like. In similar fashion, the original coating which is to be matched could be of any coating type, and typically may be an automotive finishing primer, primer surfacer; or topcoat which may be a either a monocoat, clearcoat/colorcoat composite, and the like.

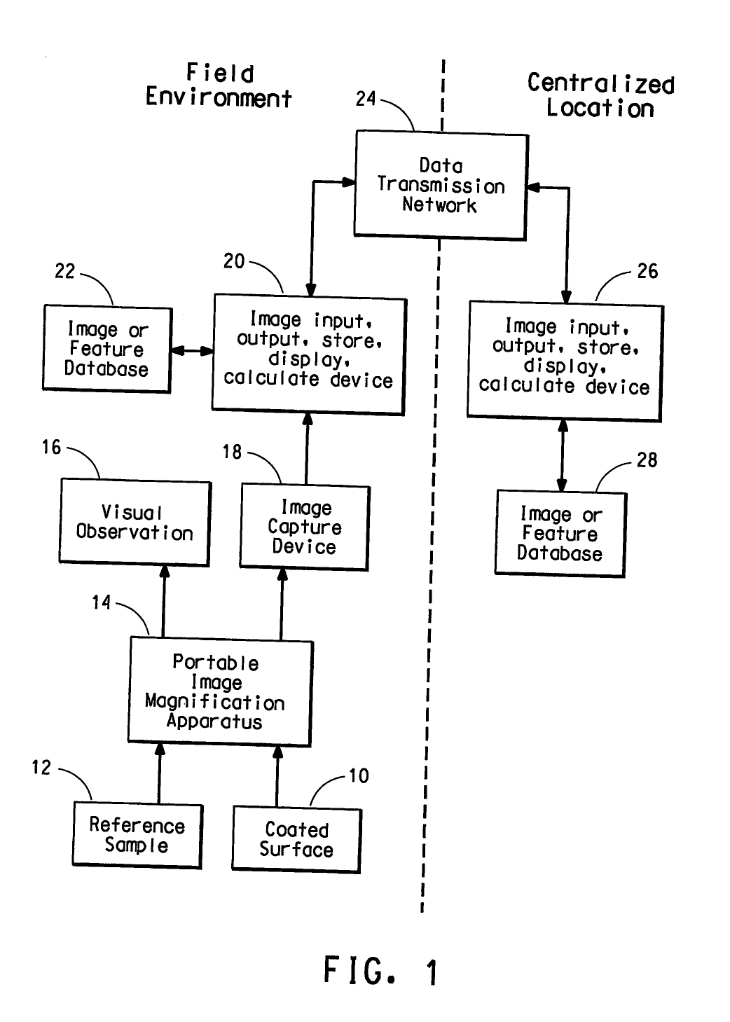

Referring to FIG. 1, which provides a flow diagram generally illustrating the method of the present invention. In the method, starting with in step 10, a coated surface which contains an effect pigment, preferably a vehicle coating with a pearl or aluminum effect pigment, is analyzed. A handheld portable image magnification apparatus, as indicated in step 14, is employed in the analysis. The magnified surface image may be visually observed in accordance with step 16, and compared with a reference library sample in the field, step 12. Alternatively, the magnified surface image may be captured with an image capturing device, step 18. If the image is captured, it may be compared with an image or feature database in according to steps 20 and 22, in the field environment.

In another embodiment of the method of the present invention, referring to FIG. 1, the magnified surface image may be captured and inputted or stored, according to steps 18 and 20. Subsequently, the captured image may then be compared with a centralized image or feature database, step 28, by transmitting the captured image through a suitable data transmission network to an image analysis device, in accordance with steps 24 and 26.

Effect pigments, as compared with conventional pigments, are those such as aluminum, pearl flakes, and the like. Comparatively, conventional pigments in the art are metallic oxides such as titanium dioxide, iron oxides of various colors, zinc oxide, carbon black, filler pigments such as talc, china clay, barytes, carbonates, silicates and a wide variety of organic colored pigments such as quinacridones, copper phthalocyanines, perylenes, azo pigments, indanthrone blues, carbazoles such as carbazole violet, isoindolinones, isoindolones, thioindigo reds, benzimilazolinones and the like.

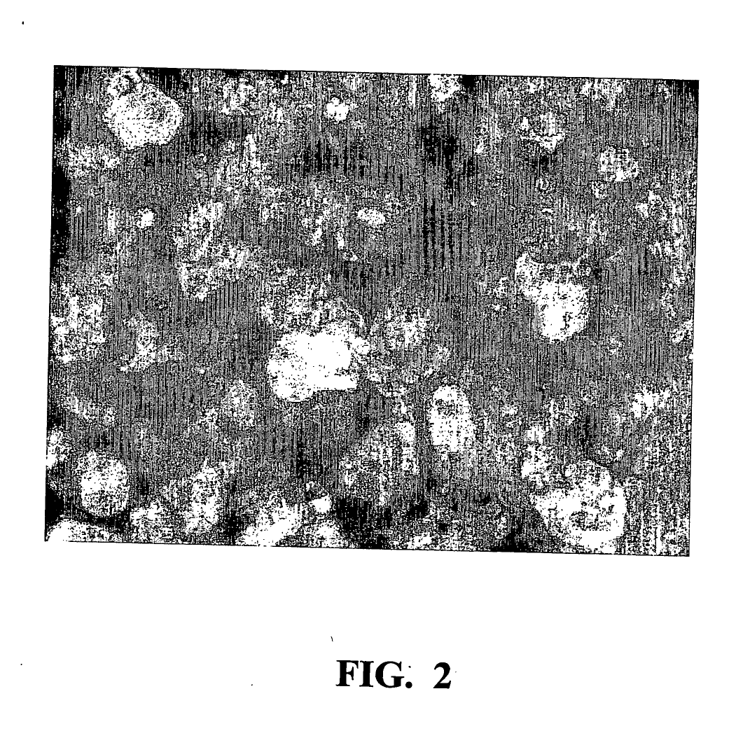

Effect pigments are analyzed and with the method of the present invention used in development of a custom metallic or pearl color formula to match a vehicle at a repair facility. This is achieved by visually detecting effect pigment properties such as size, shape, edge and surface morphology, or color, as the image of FIG. 2 illustrates. Referring to FIG. 2, it is readily apparent that analyzing and classifying the characteristics of effect pigments for color matching purposes is a difficult endeavor, especially where there is a plurality of effect pigment grades or types. A key aspect of the present invention is that notwithstanding such difficulties, the method enables an operator to effectively analyze a target coated sample's effect pigment properties, to develop an excellent color match formula, using portable equipment at a decentralized location, without necessarily possessing a high level of skill in the color matching art.

In a first preferred embodiment, the method of the present invention can be implemented at a repair facility or similar decentralized location by use of a portable magnification apparatus and reference samples, and conducting a side by side comparison. In a second embodiment, an image can be captured from the vehicle's coated surface for analysis on a laptop computer or similar image storage and display device for side by side comparison of the micro features of the vehicle and reference images. In yet a third embodiment, an image or image features of the vehicle coating obtained at the field location can be transmitted to a central location for micro feature comparison analysis.

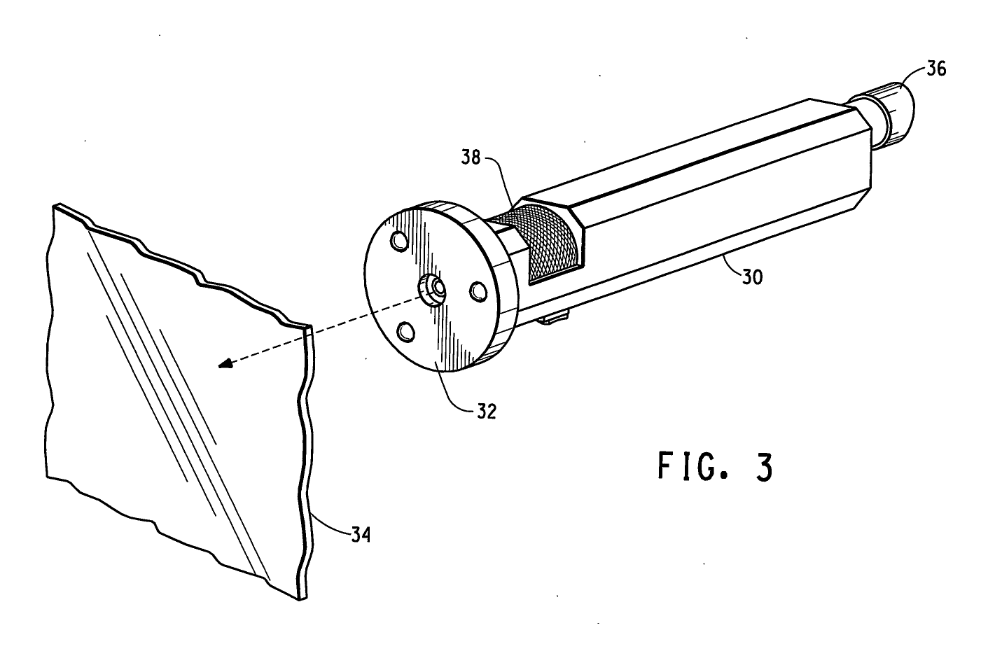

The method of the present invention utilizes an inexpensive and portable magnification apparatus at a field repair facility, to detect the effect pigment properties. Preferably, the portable magnification apparatus is a portable microscope, as shown in FIG. 3. By “portable” it is meant that the apparatus is conveniently transported and used in a variety of settings, including in the field, without the necessity for a large working surface or support.

Most preferably, the portable apparatus is a handheld device, as is shown in FIG. 3. Some examples of commercially available handheld portable microscopes include, but are not limited to, Model ME4130 from Micro Enterprises Inc, Norcross, Ga., Micromet Portable Microscope, Omex Technologies Inc, Northbrook, Ill., or Super-Compact Portable Microscope DSM-3, from Daiko Science Co Ltd, Tokyo, Japan.

Referring to FIG. 3, if a handheld portable microscope is utilized for visual observation of the effect pigments, the operator simply grasps and secures the body 30 of the handheld microscope, places the base 32 upon the coated surface to be analyzed 34, and brings his or her eye to the eyepiece 36. Once the observer is viewing the magnified image of the coated surface 34, the observer may further refine the clarity of the image by adjusting the focal length knob 32. When the observer has adequately adjusted the clarity, they should visually observe an image which has similar characteristics to that shown in FIG. 2.

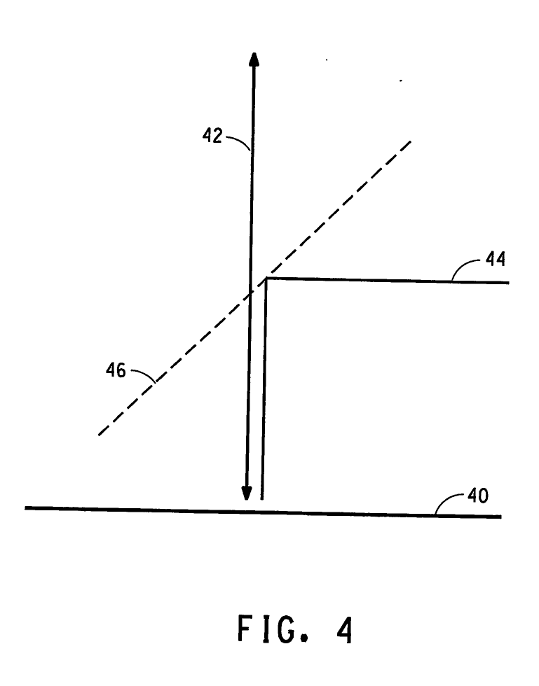

In a preferred embodiment, the portable microscope should use reflected light from the coating, using co-axial illumination as illustrated in FIG. 4. By co-axial illumination it is meant that the coating surface 40 is illuminated and observed in a configuration wherein the observation direction 42 and illumination direction 44 are parallel. This is accomplished by means of beam splitter 46 which effectively changes the direction of the illumination light 44, without eliminating the co-axially observed coating reflection 42.

The portable microscope used a preferred embodiment of the present invention should have a magnification from about 100× to 1000×. More preferably, the magnification should be from about 150× to 500×. The magnification objective of the portable microscope may be either fixed or variable. Further, the microscope could have an optional color image acquisition capability, such as, but not limited to, a color USB camera. An image acquired by such an apparatus could be analyzed in the field, or transmitted to a central facility for analysis. Any image capture step of the system preferably operates at a resolution of 0.7 μm/pixel. However, acceptable image comparisons may be done at resolutions below 3 μm/pixel.

In the event that such an image is transmitted to a central facility, such data transmission may be made by available means, such as, but not limited to, electronic mail through the internet, electronic mail through a network, uploading through a network, data or file sharing through a network, and the like. Any readily available means may be used. Other means of transmission may be readily apparent to those of skill in the art.

The method of the present invention is particularly useful for developing a color match refinish or repair coating system, when such a system contains effect pigments. Color matching procedure of effect pigment containing colors for vehicle repair requires technologies to identify the effect and conventional pigments to use in the repair paint and adjustment of the amounts of the pigments to obtain an acceptable color match. The steps of a typical procedure may be as follows:
1. Obtaining a standard sample of the effect color to be matched. The standard sample is typically an effect paint standard supplied by the vehicle OEM. Alternatively the sample can be the exterior painted surface of the vehicle to be repaired or an exterior painted car part removed from the vehicle to be repaired or a similarly painted vehicle;
2. Measuring the spectral reflectance of the standard sample in multiple aspecular directions with a multi-angle spectrophotometer. Color values are derived from the multi-angle reflectance measurements to aid in the assessment of the fitness of the color match by comparison using color difference tolerances. Our measurement system is based on U.S. Pat. No. 4,479,718, incorporated herein by reference, and employs spectral reflectance measurements at aspecular angles of 15, 45 and 110 degrees using X-Rite MA90, MA100 or MA68 spectrophotometers, available from X-Rite Incorporated, 3100 44th Street, S. W., Grandville, Mich., 49418;
3. Selecting the effect pigments to use in the repair paint from a library of effect tints available in the repair paint system. Effect pigments impart color variation with viewing direction (e.g., color travel or flop) and visual texture (sparkle, color non-uniformity) appearance to effect colors. Selection of the best matching effect pigments is critical to obtaining acceptable color match and effect appearance. The selection is made by visual comparisons to reference samples of the effect tint library by visual observation and/or by comparisons with the aid of a microscope;
4. Determining the color formula of the repair paint using a computer color matching system for effect colors to identify the conventional pigments and to estimate the pigment amounts needed to match the sample. A pigment mixture model relates the amounts of the effect and conventional pigments to observed reflectance values at multiple aspecular angles. The software combines the selected effect pigments with combinations of conventional pigments and estimates the amounts of the pigments required to minimize the color difference between the sample and the repair paint formulation. Criteria such as color difference and metamerism index value are used to choose the best formula. A test sample of the repair formula is prepared; and
5. Preparing a paint from the color formula and spraying such paint on a test sample. If the test sample is not an acceptable match to the standard sample then variation of the amounts of pigments in the formula and/or addition of new pigments to the formula are necessary to adjust the formula. The test sample color difference relative to the standard sample is determined. The computed sensitivity of color difference of the formula to changes in the amounts of the formula pigments is applied to calculate an adjustment to reduce the error between test and standard samples. Alternatively an experienced color technician makes a correction to the color formula based on skilled experience in effect color adjustment. The adjustment method is repeated until an acceptable color match is obtained.

As earlier stated, the method of the present invention analyzes effect pigment microscopic features. Microscopic morphology, color, and size features are used to identify effect pigment types. The morphology of edges and surfaces of flakes are good indicators for effect pigment substrate type. For example there are two classes of aluminum effect pigments. The first class is described as having a “corn-flake” appearance, i.e. flat but irregular. This class has edge features that show irregular shape with rough edges and surface features that show an un-smooth or rumpled appearance. The other class of aluminum effect pigments is described as having a “silver coin” appearance. For this class the morphology features are smooth edges with rounded shaped and smooth, flat surfaces. Size and color are additional features for aluminum pigment classification. The maximum diameter of flakes is used to classify aluminum flake grades that vary from fine to medium, coarse and extra coarse appearance. Larger flakes have more sparkle and more color travel. The maximum diameters of flakes are generally in the range 15 to 70 micrometers and can be measured by comparison to an eyepiece reticle or by measurement using image capture and image methodizing software. Most aluminum flake types are silver colored but some have a single color hue (yellow, red, blue, etc.) due to deposition of an absorbing colorant onto an aluminum substrate.

Another large class of effect pigments is pearlescent, or pearl flakes. These are distinguishable from aluminum flakes by microscopic features. Pearl effect pigments have multiple colors and have a less rounded shape than aluminum flakes. There are two major classes with differing morphology. One class has a layer of dielectric material deposited onto mica substrates and the other has similar material deposited on synthetic aluminum oxide substrates. The mica pearl type has sharp, angular edges and smooth surfaces that appear to have a stepped thickness. These mica pearl pigments typically have multiple colors with 2 or 3 dominant colors and others present with lower frequency. Multiple colors may occur on a single flake. Specific grades also vary in maximum size from fine to medium to coarse in the range 15 to 70 micrometers. The aluminum oxide pearls have similar color and size features. They are distinguished by morphology features of very sharp edges, angular shape and extremely flat, smooth surfaces.

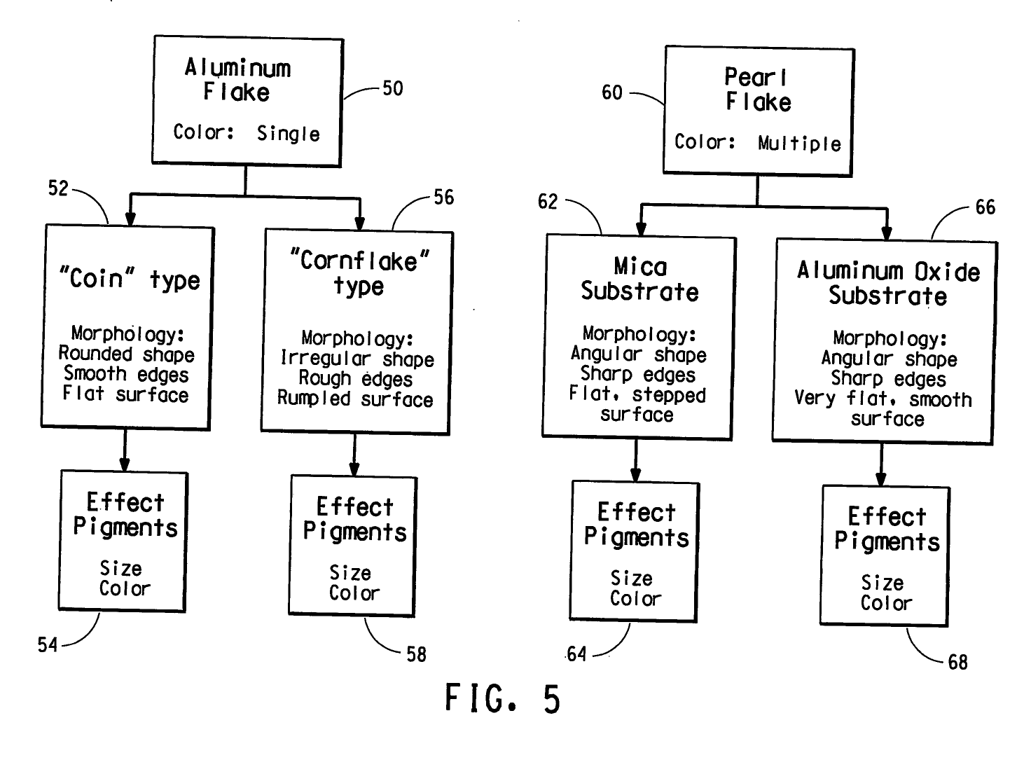

In the method of the present invention, a multiple step classification method may be used to select effect pigments for color matching. An example effect color test sample image is shown in FIG. 2. An example of a useful classification scheme is shown in FIG. 5, although any classification scheme which is readily apparent to those of skill in the art may be used.

Referring to the classification scheme in FIG. 5, classifying the effect pigments by color features into aluminum and pearl types may be done, block 50 or 60. The aluminum effect pigments have a single dominant color while pearl flakes have multiple colors present. In the paint sample image of FIG. 2 it is readily apparent that there are flakes of both types present, that is, silver aluminum flakes and multiple color pearl flakes.

Classifying effect pigment substrate type by observation of morphology features, in accordance with FIG. 5 blocks 52, 56, 62, or 66, may then be conducted. In the magnified coating image of FIG. 2, the aluminum flakes are rounded, smooth edged, and flat surfaces indicating a “coin” type aluminum flake, and would be classified in FIG. 5 block 52. Conversely, the aluminum flake may be irregularly shaped, rough edged, and coarsely surfaced, indicating a “cornflake” type aluminum flake, block 56. Also, in the coating image of FIG. 2, the pearl flake has an angular shape, sharp edges and flat stepped surfaces indicating mica substrate pearl, FIG. 5 block 62. Conversely, if the pearl flake had an angular shape, sharp edges, but a very flat smooth surface, it would be aluminum oxide substrate based.

The last step of a classification method may require an estimation of the maximum diameters of flakes and evaluation of the predominant colors of the flakes, FIG. 5 blocks 54, 58, 64, or 68. This allows differentiation between the individual effect pigments within each class conducted. In the magnified coating image of FIG. 2, the coin-type aluminum flakes have maximum diameter of 40 micrometers and silver color indicating a medium grade aluminum effect pigment. The mica pearl flakes in the magnified image of FIG. 2 have maximum diameter of 50 micrometers, and have pale red, pale green and pale yellow dominant colors. These features indicate a medium size copper mica pearl effect pigment. In a preferred embodiment, the identification of the matching effect pigments can be confirmed by successive visual observation of the reference and test samples through the image magnification apparatus or by side by side comparison of the reference and test sample images.

Various modifications, alterations, additions or substitutions of this invention will be apparent to those skilled in the art without departing from the spirit and scope of this invention. This invention is not limited by the illustrative embodiments set forth herein, but rather is defined by the following claims.

We claim:

1. A method for identifying the effect pigment, or pigments, of a coating, said method comprising the steps of:
(a) visually observing effect pigment properties of the coating of a vehicle to be color matched, in a field location with a portable magnification apparatus; and
(b) comparing said effect pigment properties, with properties of physical reference samples of available effect pigments, thus enabling precise effect pigment or pigments selection to use in the development of said color matched formula.

2. The method of claim 1 wherein said portable magnification apparatus uses reflected light observation with co-axial illumination in the magnification range from about 100× to 1000×.

3. The method of claim 1 wherein said portable magnification apparatus uses reflected light observation with co-axial illumination in the magnification range from about 150× to 500×.

4. The method of claim 1 wherein said portable magnification apparatus is a portable microscope.

5. The method of claim 1 wherein said portable magnification apparatus is a handheld portable microscope.

6. The method of claim 1, wherein said properties of physical reference samples of available effect pigments, further comprises features derived from images of said reference samples.

7. A method for identifying the effect pigment, or pigments, of a coating, comprising the steps of:
(a) obtaining images of the coating of a vehicle to be matched, in a field location with a portable magnification apparatus; and
(b) comparing, in a field or centralized laboratory location, the effect pigment properties of said images of the coating of a vehicle to be matched, with the properties of images derived from physical reference samples of available effect pigments, thus enabling precise effect pigment or pigments selection to use in the development of said color matched formula.

8. The method of claim 7 wherein:
(a) said effect pigment properties images of the coating of a vehicle to be matched, further comprise features derived from said images; and
(b) said properties of images derived from physical reference samples of available effect pigments, further comprise features derived from images of said reference samples.

9. The method of claim 7, wherein the portable magnification apparatus is a handheld device.

10. The use of the method of claim 1 as part of a system for developing a color matched formula for a vehicle repair paint.

11. The use of the method of claim 7 as part of a system for developing a color matched formula for a vehicle repair paint.

12. The use of the method of claim 1 to develop a color matched colorcoat/clearcoat composite finish formula for a vehicle repair paint.

13. The use of the method of claim 7 to develop a color matched colorcoat/clearcoat composite finish formula for a vehicle repair paint.

14. The use of the method of claim 1 to develop a color matched monocoat formula for a vehicle repair paint.

15. The use of the method of claim 7 to develop a color matched monocoat formula for a vehicle repair paint.
